(19) United States
(12) Patent Application Publication
(10) Pub. No.: US 2015/0168460 A1
(43) Pub. Date: Jun. 18, 2015

(54) APPARATUS FOR DETECTING CLOCK SIGNAL AND SYSTEM FOR DETECTING CLOCK SIGNAL USING THE SAME

(71) Applicant: SAMSUNG ELECTRO-MECHANICS CO., LTD., Suwon-Si (KR)

(72) Inventor: Kyung Uk KIM, Suwon-Si (KR)

(73) Assignee: SAMSUNG ELECTRO-MECHANICS CO., LTD., Suwon-Si (KR)

(21) Appl. No.: 14/245,753

(22) Filed: Apr. 4, 2014

(30) Foreign Application Priority Data
Dec. 17, 2013 (KR) 10-2013-0156990

(51) Int. Cl. G01R 17/02

(52) U.S. Cl. CPC G01R 17/02

(57) ABSTRACT

An apparatus for detecting a clock signal may include a first voltage generation unit storing electrical charges if an input signal has a high level while discharging the electric charges if the input signal has a low level so as to generate a first voltage, a second voltage generation unit storing electrical charges if the input signal has a low level while discharging the electric charges if the input signal has a high level so as to generate a second voltage, and a signal detection unit comparing the first voltage or the second voltage with a reference voltage so as to detect whether a clock signal or operating power is being input.

### CROSS-REFERENCE TO RELATED APPLICATION

This application claims the benefit of Korean Patent Application No. 10-2013-0156990, filed on Dec. 17, 2013, with the Korean Intellectual Property Office, the disclosure of which is incorporated herein by reference.

### BACKGROUND

The present disclosure relates to an apparatus for detecting a clock signal and a system for detecting a clock signal using the same.

In general, various actuators, such as actuators used in camera modules in mobile terminals, employ an apparatus for detecting a clock signal.

Such an actuator is powered by a battery through a main board in a mobile terminal.

Current from such a battery in a mobile terminal is consumed by various actuators installed in the mobile terminal. A technique of reducing power consumption by way of turning off actuators when no operating power is supplied to the actuators is thus desperately required.

In the related art, however, an apparatus for detecting a clock signal detects whether a clock signal is contained in an input signal but cannot detect whether operating power is being input. Accordingly, an additional power-saving module is required to turn an actuator to which no operating power is being input off.

Moreover, in the related art, an apparatus for detecting a clock signal employs a frequency divider circuit to detect a clock signal. However, as mobile terminals are reduced in size, the apparatus needs to employ a simpler circuit to detect a clock signal.

### SUMMARY

An exemplary embodiment in the present disclosure may provide an apparatus for detecting a clock signal being reduced in size and reducing power consumption by way of detecting whether operating power or a clock signal is present in an input signal, and a system for detecting a clock signal using the same.

According to an exemplary embodiment in the present disclosure, an apparatus for detecting a clock signal may include: a first voltage generation unit storing electrical charges if an input signal has a high level while discharging the electric charges if the input signal has a low level so as to generate a first voltage; a second voltage generation unit storing electrical charges if the input signal has a low level while discharging the electric charges if the input signal has a high level so as to generate a second voltage; and a signal detection unit comparing the first voltage or the second voltage with a reference voltage so as to detect whether a clock signal or operating power is being input.

The first voltage generation unit may include: a first switching unit outputting a high signal if the input signal has a high level while outputting a low signal if the input signal has a low level; and a first charging/discharging unit storing electrical charges upon receiving the high signal from the first switching unit while discharging the electric charges upon receiving the low signal.

The first switching unit may be a bidirectional switch receiving an inverted or non-inverted input signal so as to output a high or low signal.

The first charging/discharging unit may include: a first capacitor connected between an output terminal of the first switching unit and a ground; and a first discharge switching unit connected to the first capacitor in parallel so as to discharge electric charges in the first capacitor if the input signal has a low level.

The first discharge switching unit may be a first PMOS transistor that is connected between the output terminal of the first switching unit and the ground and receives an inverted signal of the input signal at a gate terminal thereof.

The second voltage generation unit may include: a second switching unit outputting a high signal if the input signal has a low level while outputting a low signal if the input signal has a high level; and a second charging/discharging unit storing electrical charges upon receiving the high signal from the second switching unit while discharging the electric charges upon receiving the low signal.

The second switching unit may be a bidirectional switch receiving an inverted or non-inverted input signal so as to output a high or low signal.

The second charging/discharging unit may include: a second capacitor connected between an output terminal of the second switching unit and a ground; and a second discharge switching unit connected to the second capacitor in parallel so as to discharge electric charges in the second capacitor if the input signal has a low level.

The second discharge switching unit may be a second PMOS transistor that is connected between the output terminal of the second switching unit and the ground and receives a non-inverted input signal at a gate terminal thereof.

The signal detection unit may output operating power detection signal if the first voltage is greater than the reference voltage.

The signal detection unit may output a clock detection signal if the first voltage and the second voltage are less than the reference voltage.

The signal detection unit may include: a first comparison unit comparing the first voltage with the reference voltage; a second comparison unit comparing the second voltage with the reference voltage; and a determination unit outputting operating power detection signal or a clock detection signal based on a comparison result from the first comparison unit or the second comparison unit.

The first comparison unit or the second comparison unit may be a hysteresis comparator.

The determination unit may output the operating power detection signal if an output from the first comparison unit is high while an output from the second comparison unit is low.

The determination unit may output the clock detection signal if an output from the first comparison unit is low while an output from the second comparison unit is low.

According to an exemplary embodiment in the present disclosure, a system for detecting a clock signal may include: an oscillator outputting a clock signal; an apparatus for detecting a clock signal by detecting whether a clock signal or operating power is being input using an inverted or a non-inverted external input signal; a controller receiving and outputting the external input signal if a clock signal is detected in the external input signal, receiving and outputting a clock signal from the oscillator if no clock signal is detected in the external input signal but operating power is detected therein, and outputting a signal indicating a sleep mode if neither a clock signal nor operating power is detected in the external input signal.

The apparatus for detecting a clock signal may include: a first voltage generation unit storing electrical charges if an input signal has a high level while discharging the electric charges if the input signal has a low level so as to generate a first voltage; a second voltage generation unit storing electrical charges if the input signal has a low level while discharging the electric charges if the input signal has a high level so as to generate a second voltage; and a signal detection unit comparing the first voltage or the second voltage with a reference voltage so as to detect whether a clock signal or operating power is being input.

The first voltage generation unit may include: a first switching unit outputting a high signal if the input signal has a high level while outputting a low signal if the input signal has a low level; and a first charging/discharging unit storing electrical charges upon receiving the high signal from the first switching unit while discharging the electric charges upon receiving the low signal.

The first switching unit may be a bidirectional switch receiving an inverted or non-inverted input signal so as to output a high or low signal.

The first charging/discharging unit may include: a first capacitor connected between an output terminal of the first switching unit and the ground; and a first discharge switching unit connected to the first capacitor in parallel so as to discharge electric charges in the first capacitor if the input signal has a low level.

The first discharge switching unit may be a first PMOS transistor that is connected between the output terminal of the first switching unit and the ground and receives an inverted signal of the input signal at a gate terminal thereof.

The second voltage generation unit may include: a second switching unit outputting a high signal if the input signal has a low level while outputting a low signal if the input signal has a high level; and a second charging/discharging unit storing electrical charges upon receiving the high signal from the second switching unit while discharging the electric charges upon receiving the low signal.

The second switching unit may be a bidirectional switch receiving an inverted or non-inverted input signal so as to output a high or low signal.

The second charging/discharging unit may include: a second capacitor connected between an output terminal of the first switching unit and the ground; and a second discharge switching unit connected to the second capacitor in parallel so as to discharge electric charges in the second capacitor if the input signal has a low level.

The second discharge switching unit may be a second PMOS transistor that is connected between the output terminal of the second switching unit and the ground and receives a non-inverted input signal at a gate terminal thereof.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of an apparatus for detecting a clock signal according to an exemplary embodiment of the present disclosure;

FIG. 2 is a block diagram of examples of a first voltage generation unit and a second voltage generation unit shown in FIG. 1;

FIG. 3 is a block diagram of other examples of the first voltage generation unit and the second voltage generation unit shown in FIG. 1;

FIG. 4 is a diagram of an example of a signal detection unit shown in FIG. 1;

FIG. 5 is a set of graphs showing waveforms of voltages at nodes; and

FIG. 6 is a block diagram of a system for detecting a clock signal according to an exemplary embodiment of the present disclosure.

### DETAILED DESCRIPTION

Exemplary embodiments of the present disclosure will now be described in detail with reference to the accompanying drawings.

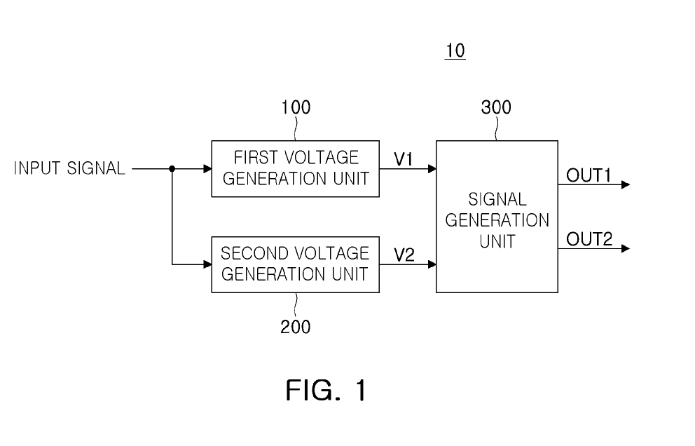

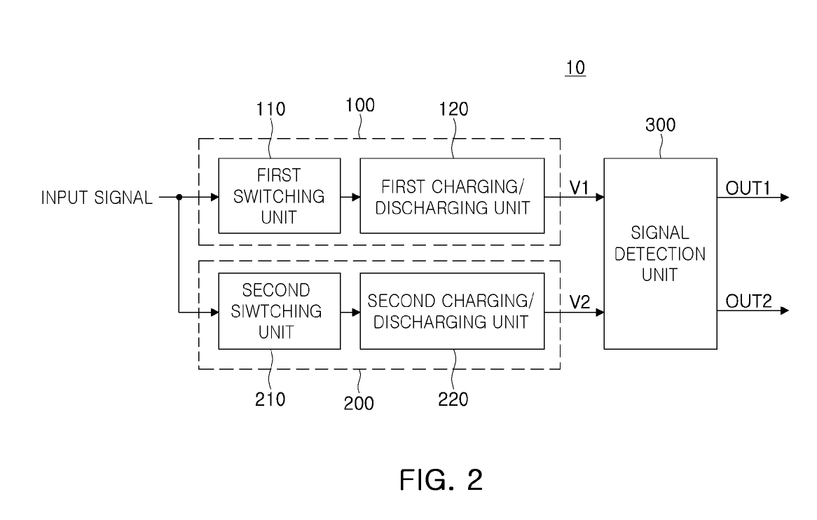

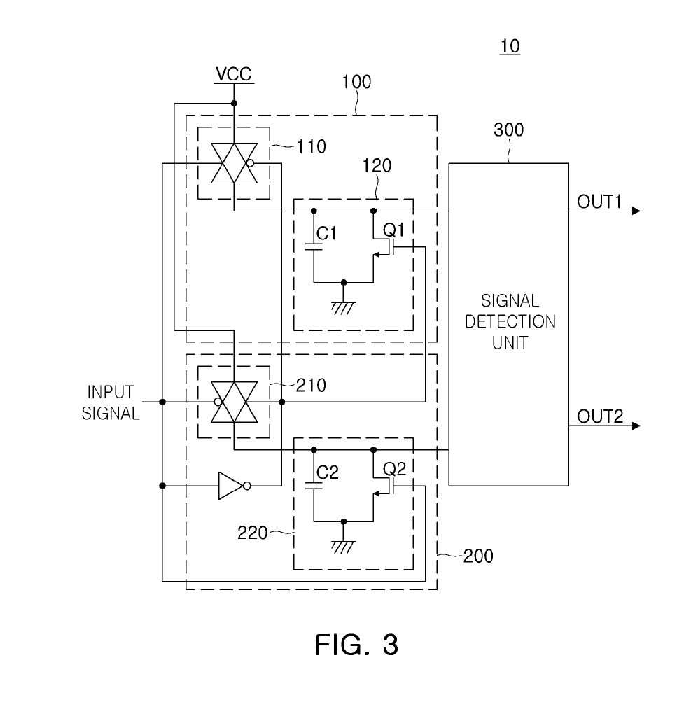

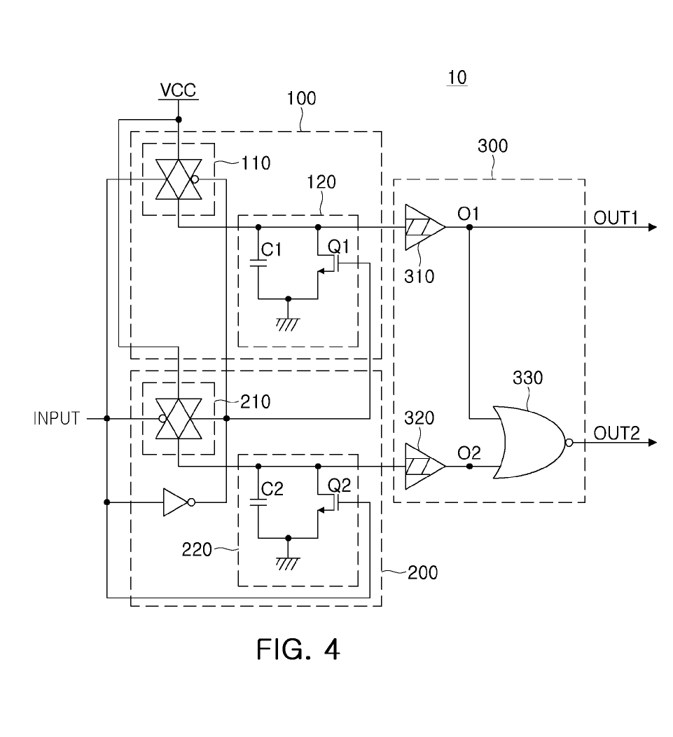

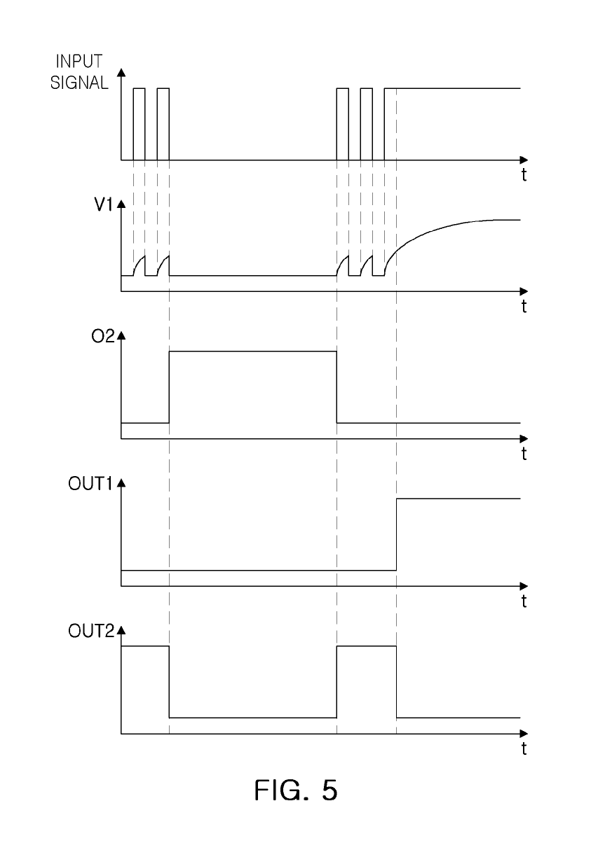

FIG. 1 is a block diagram of an apparatus for detecting a clock signal according to an exemplary embodiment of the present disclosure; FIG. 2 is a block diagram of examples of a first voltage generation unit and a second voltage generation unit shown in FIG. 1; FIG. 3 is a block diagram of other examples of the first voltage generation unit and the second voltage generation unit shown in FIG. 1; FIG. 4 is a diagram of an example of a signal detection unit shown in FIG. 1; and FIG. 5 is a set of graphs showing waveforms of voltages at nodes.

Referring to FIG. 1, an apparatus 10 for detecting a clock signal according to an exemplary embodiment of the present disclosure may include a first voltage generation unit 100, a second voltage generation unit 200, and a signal detection unit 300.

The first voltage generation unit 100 may generate a comparison voltage used for detecting whether a clock signal or operating power is being input. Specifically, the first voltage generation unit 100 may charge electric charges when an input signal externally input is high while it may discharge electric charges when the input signal has a low level, so as to generate a first voltage V1.

The second voltage generation unit 200 may generate a comparison voltage, like the first voltage generation unit 100. Specifically, the second voltage generation unit 200 may charge electric charges when an input signal externally input is low while it may discharge electric charges when the input signal has a high level, so as to generate a second voltage V2.

In an exemplary embodiment, the first voltage generation unit 100 and the second voltage generation unit 200 may include switching units 110 and 210 and charging/discharging units 120 and 220, respectively, as shown in FIG. 2.

Specifically, the first voltage generation unit 100 may include the first switching unit 110 that outputs a high signal when an input signal externally input is high and outputs a low signal when the input signal has a low level, and a first charging/discharging unit 120 that charges electric charges upon receiving the high signal output from the first switching unit 110 and discharges the electric charges upon receiving the low signal.

Here, the first switching unit 110 may be a bidirectional switch 110 receiving an inverted or non-inverted input signal so as to output a high or low signal, as shown in FIG. 3.

In addition, the first charging/discharging unit 120 may include a first capacitor C1 connected between the output terminal of the first switching unit 110 and a ground, and a first discharge switching unit Q1 connected to the first capacitor C1 in parallel so as to discharge electric charges charged in the first capacitor C1 when the input signal has a low level.

In an exemplary embodiment, the fist discharge switching unit Q1 may be a first PMOS transistor Q1 that is connected between the output terminal of the first switching unit 110 and the ground and receives an inverted signal of the input signals at its gate terminal.

Specifically, the first PMOS transistor Q1 has its drain terminal connected to the output terminal of the first switching unit 110, has its source terminal connected to the ground, and receives an inverted input signals at its gate terminal.

The second voltage generation unit 200 may be operated in the opposite way to the first switching unit 100. Specifically, the second voltage generation unit may include a second switching unit 210 that outputs a high signal when an input signal externally input is low and outputs a low signal when the input signal has a high level, and a second charging/discharging unit 220 that charges electric charges upon receiving the high signal from the second switching unit 210 and discharges the electric charges upon receiving the low signal.

Here, the second switching unit 210 may be a bidirectional switch receiving an inverted or non-inverted input signal so as to output a high or low signal from the supply voltage Vcc.

In an exemplary embodiment, the second charging/discharging unit 220 may include a second capacitor C2 connected between the output terminal of the second switching unit 210 and the ground, and a second discharge switching unit C2 connected to the second capacitor C2 in parallel so as to discharge electric charges charged in the second capacitor Q2 when the input signal has a low level.

Here, the second discharge switching unit Q2 may be a second PMOS transistor Q2 that is connected between the output terminal of the second switching unit 210 and the ground and receives a non-inverted input signal at its gate terminal.

The signal detection unit 300 may compare the first voltage V1 or the second voltage V2 with a predetermined reference voltage so as to detect whether a clock signal or operating power is being input.

Here, the signal detection unit 300 may output operating power detection signal if the first voltage V1 is greater than the predetermined reference voltage.

Further, the signal detection unit 300 may output a clock detection signal if the first voltage V1 and the second voltage V2 are less than the predetermined reference voltage.

In an exemplary embodiment, the signal detection unit 300 may include a first comparison unit 310 comparing a first voltage V1 with the predetermined reference voltage, a second comparison unit 320 comparing a second voltage V2 with the predetermine reference voltage, and a determination unit 330 outputting operating power detection signal or a clock detection signal depending on a comparison result from the first comparison unit 310 or the second comparison unit 320, as shown in FIG. 4. Here, the first comparison unit 310 or the second comparison unit 320 may be implemented as a hysteresis comparator.

The determination unit 330 may serve to output operating power detection signals or a clock detection signal using the first voltage V1 and the second voltage V2. Specifically, the determination unit 330 may output operating power detection signal when the output OUT1 from the first comparison unit 310 is high and the output O2 from the second comparison unit 320 is low, as shown in FIG. 5. In addition, the determination unit 330 may output a clock detection signal when the output OUT1 from the first comparison unit 310 is low and the output O2 from the second comparison unit 320 is low.

Table 1 below shows input signals and states at nodes V1, V2, O1, O2, OUT1, and OUT2.

TABLE 1

| Input Signal | | V1 | V2 | O1 (OUT1) | O2 | OUT2 |
|---|---|---|---|---|---|---|
| Clock | Rising | Charge | Discharge | LOW | LOW | HIGH |
| Signal | Edge | | | | | |
| | Falling | Discharge | Charge | LOW | LOW | HIGH |
| | Edge | | | | | |
| Operating | DC HIGH | Charge | Discharge | HIGH | LOW | LOW |
| power | DC LOW | Discharge | Charge | LOW | HIGH | LOW |

As can be seen from Table 1, when an input signal contains a clock signal, V1 is charged at a rising edge while it is discharged at a falling edge. In this instance, the first comparison unit 310 outputs a low signal. Likewise, V2 is discharged at a rising edge while it is charged at a falling edge, and accordingly the second comparison unit 320 outputs a low signal.

Upon receiving low signals from the first comparison unit 310 and the second comparison unit 320, the determination unit 330 may output a clock detection signal.

If an input signal does not contain a clock signals and operating power DC HIGH is being input, V1 is charged and V2 is discharged. In this instance, the first comparison unit 310 may output a high signal if V1 is charged so that it becomes greater than the predetermined reference voltage. The determination unit 330 may receive the high signal so as to output operating power detection signal.

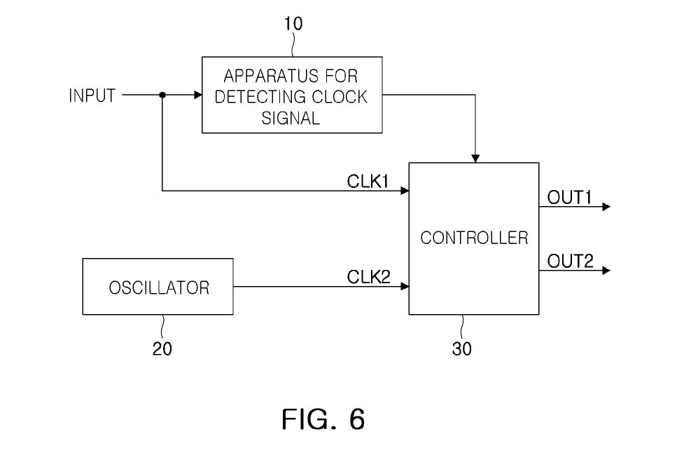

FIG. 6 is a block diagram of a system for detecting a clock signal according to an exemplary embodiment of the present disclosure.

Referring to FIG. 6, the system for detecting a clock signal according to the exemplary embodiment of the present disclosure may include an apparatus 10 for detecting a clock signal detecting whether a clock signal or operating power is being input, an oscillator 20, and a controller 30 outputting a clock signal or operating power.

The apparatus 10 for detecting a clock signal may detect whether a clock signal or operating power is being input by using an inverted or a non-inverted external input signal.

Specifically, the apparatus 10 for detecting a clock signal may output a clock detection signal to the controller 30 if a clock signal is detected in an input signal, and may detect whether operating power is being input if no click signal is detected so as to transmit the result to the controller 30.

In an exemplary embodiment, the apparatus 10 for detecting a clock signal may include a first voltage generation unit 100 storing electrical charges when an input signal has a high level and disstoring electrical charges when the input signals is low so as to generate a first voltage V1, a second voltage generation unit 200 storing electrical charges when an input signal has a low level and disstoring electrical charges when the input signals is high so as to generate a second voltage V2, and a signal detection unit comparing the first voltage V1 or the second voltage V2 with a predetermined reference voltage so as to detect whether a clock signal or operating power is being input.

The specific configuration of the apparatus 10 for detecting a clock signal has been already described, and thus will not be repeated.

The oscillator 20 generates a clock signal so as to output it to the controller 30.

The controller 30 may output signals at different modes depending on whether an input signal contains a clock signal. For example, the controller 30 may receive an external input signal to output it when the external input signal contains a clock signal, may receive a clock signal from the oscillator 20 to output it when the external input signal does not contain a clock signal but operating power is detected, and may output a sleep mode signal when neither clock signal nor operating power is detected in the external input signal.

In another exemplary embodiment, if an input signal does not contain a clock signal, the controller 30 may output an operation mode signal or a sleep mode signal depending on whether operating power is being input. Further, if the input signal contains a clock signal, the controller 30 may output the clock signal in the input signal if the amplitude of the clock signal in the input signals is greater than a predetermined reference signal, and may output a clock signal generated by the oscillator 20 otherwise.

As set forth above, according to exemplary embodiments of the present disclosure, an apparatus for detecting a clock signal has a smaller size and reducing power consumption of an apparatus including it by way of detecting whether operating power or a clock signal is present in an input signal.

While exemplary embodiments have been shown and described above, it will be apparent to those skilled in the art that modifications and variations could be made without departing from the spirit and scope of the present disclosure as defined by the appended claims.

What is claimed is:

1. An apparatus for detecting a clock signal, comprising:
a first voltage generation unit configured to store electrical charges if an input signal has a high level while discharge the electric charges if the input signal has a low level so as to generate a first voltage;
a second voltage generation unit configured to store electrical charges if the input signal has a low level while discharge the electric charges if the input signal has a high level so as to generate a second voltage; and
a signal detection unit configured to compare the first voltage or the second voltage with a reference voltage so as to detect whether a clock signal or operating power is being input.

2. The apparatus of claim 1, wherein the first voltage generation unit includes:
a first switching unit configured to output a high signal if the input signal has a high level while output a low signal if the input signal has a low level; and
a first charging/discharging unit configured to store electrical charges upon receiving the high signal from the first switching unit while discharge the electric charges upon receiving the low signal.

3. The apparatus of claim 2, wherein the first switching unit is a bidirectional switch receiving an inverted or non-inverted input signal so as to output a high or low signal.

4. The apparatus of claim 2, wherein the first charging/discharging unit includes:
a first capacitor connected between an output terminal of the first switching unit and a ground; and
a first discharge switching unit connected to the first capacitor in parallel so as to discharge electric charges in the first capacitor if the input signal has a low level.

5. The apparatus of claim 4, wherein the first discharge switching unit is a first PMOS transistor that is connected between the output terminal of the first switching unit and the ground and receives an inverted signal of the input signal at a gate terminal thereof.

6. The apparatus of claim 1, wherein the second voltage generation unit includes:
a second switching unit configured to output a high signal if the input signal has a low level while output a low signal if the input signal has a high level; and
a second charging/discharging unit configured to store electrical charges upon receiving the high signal from the second switching unit while discharge the electric charges upon receiving the low signal.

7. The apparatus of claim 6, wherein the second switching unit is a bidirectional switch receiving an inverted or non-inverted input signal so as to output a high or low signal.

8. The apparatus of claim 6, wherein the second charging/discharging unit includes:
a second capacitor connected between an output terminal of the second switching unit and a ground; and
a second discharge switching unit connected to the second capacitor in parallel so as to discharge electric charges in the second capacitor if the input signal has a low level.

9. The apparatus of claim 8, wherein the second discharge switching unit is a second PMOS transistor that is connected between the output terminal of the second switching unit and the ground and receives a non-inverted input signal at a gate terminal thereof.

10. The apparatus of claim 1, wherein the signal detection unit outputs operating power detection signal if the first voltage is greater than the reference voltage.

11. The apparatus of claim 1, wherein the signal detection unit outputs a clock detection signal if the first voltage and the second voltage are less than the reference voltage.

12. The apparatus of claim 1, wherein the signal detection unit includes:
a first comparison unit configured to compare the first voltage with the reference voltage;
a second comparison unit configured to compare the second voltage with the reference voltage; and
a determination unit configured to output operating power detection signal or a clock detection signal based on a comparison result from the first comparison unit or the second comparison unit.

13. The apparatus of claim 12, wherein the first comparison unit or the second comparison unit is a hysteresis comparator.

14. The apparatus of claim 12, wherein the determination unit outputs the operating power detection signal if an output from the first comparison unit is high while an output from the second comparison unit is low.

15. The apparatus of claim 12, wherein the determination unit outputs the clock detection signal if the output from the first comparison unit is low while the output from the second comparison unit is low.

16. A system for detecting a clock signal, comprising:
an oscillator configured to output a clock signal;
an apparatus for detecting a clock signal by detecting whether a clock signal or operating power is being input using an inverted or a non-inverted external input signal;
a controller configured to receive and output the external input signal if a clock signal is detected in the external input signal, receive and output a clock signal from the oscillator if no clock signal is detected in the external input signal but operating power is detected therein, and output a signal indicating a sleep mode if neither a clock signal nor operating power is detected in the external input signal.

17. The system of claim 16, wherein the apparatus for detecting a clock signal includes:
a first voltage generation unit configured to store electrical charges if an input signal has a high level while discharging the electric charges if the input signal has a low level so as to generate a first voltage;
a second voltage generation unit configured to store electrical charges if the input signal has a low level while discharge the electric charges if the input signal has a high level so as to generate a second voltage; and
a signal detection unit configured to compare the first voltage or the second voltage with a reference voltage so as to detect whether a clock signal or operating power is being input.

18. The system of claim 17, wherein the first voltage generation unit includes:
a first switching unit configured to output a high signal if the input signal has a high level while output a low signal if the input signal has a low level; and
a first charging/discharging unit configured to store electrical charges upon receiving the high signal from the first switching unit while discharge the electric charges upon receiving the low signal.

19. The system of claim 18, wherein the first switching unit is a bidirectional switch receiving an inverted or non-inverted input signal so as to output a high or low signal.

20. The system of claim 18, wherein the first charging/discharging unit includes:
a first capacitor connected between an output terminal of the first switching unit and the ground; and
a first discharge switching unit connected to the first capacitor in parallel so as to discharge electric charges in the first capacitor if the input signal has a low level.

21. The system of claim 20, wherein the first discharge switching unit is a first PMOS transistor that is connected between the output terminal of the first switching unit and the ground and receives an inverted signal of the input signal at a gate terminal thereof.

22. The system of claim 18, wherein the second voltage generation unit includes:
a second switching unit configured to output a high signal if the input signal has a low level while output a low signal if the input signal has a high level; and
a second charging/discharging unit configured to store electrical charges upon receiving the high signal from the second switching unit while discharge the electric charges upon receiving the low signal.

23. The system of claim 22, wherein the second switching unit is a bidirectional switch receiving an inverted or non-inverted input signal so as to output a high or low signal.

24. The system of claim 22, wherein the second charging/discharging unit includes:
a second capacitor connected between an output terminal of the second switching unit and the ground; and
a second discharge switching unit connected to the second capacitor in parallel so as to discharge electric charges in the second capacitor if the input signal has a low level.

25. The system of claim 24, wherein the second discharge switching unit is a second PMOS transistor that is connected between the output terminal of the second switching unit and the ground and receives a non-inverted input signal at a gate terminal thereof.
